(19) United States
(12) Patent Application Publication
(10) Pub. No.: US 2006/0186555 A1
(43) Pub. Date: Aug. 24, 2006

(54) Semiconductor device with chip-on-board structure

(75) Inventors: Chang-Il Son, Yongin-city (KR); Sam-Yong Bahng, Seongnam-city (KR)

Correspondence Address: HARNESS, DICKEY & PIERCE, P.L.C., P.O. BOX 8910, RESTON, VA, 20195, US

(73) Assignee: Samsung Electronics Co., LTD.

(21) Appl. No.: 11/338,717

(22) Filed: Jan. 25, 2006

(30) Foreign Application Priority Data
Jan. 31, 2005 (KR) 2005-08675

(51) Int. Cl. H01L 23/48; H01L 23/52; H01L 29/40

(52) U.S. Cl. 257/786

(57) ABSTRACT

A semiconductor device may include a chip-on-board (COB) substrate having bonding patterns. A semiconductor chip having bonding pads may be electrically connected to the bonding patterns and may be arranged on the COB substrate, and the semiconductor chip may have a square shape and the bonding pads of the semiconductor chip may be arranged along at least two sides of the semiconductor chip so as to form a desired angle with respect to the bonding patterns.

### PRIORITY CLAIM

A claim of priority under 35 U.S.C. § 119 is made to Korean Patent Application 2005-08675 filed on Jan. 31, 2005, the entire contents of which are hereby incorporated by reference.

### FIELD OF THE INVENTION

Example embodiments of the present invention relate to a semiconductor device. In particular, example embodiments of the present invention relate to a semiconductor device having a Chip-On-Board (COB) structure.

### BACKGROUND OF THE INVENTION

Semiconductor integrated circuit devices with higher density and/or higher speed may require additional input/output pins for improve performance. However, the size of semiconductor integrated circuit devices continues to shrink in order to satisfy a need for even smaller electronic devices. To meet the conflicting requirements between smaller area and higher pin density, chip-on-board (COB) structure have been developed. In a COB structure, a semiconductor integrated circuit device (IC), for example, a bare chip may be directly provided on a printed circuit board (PCB).

COB structure may be used for memory cards. As it is well known, memory cards have been developed for applications such as storage of moving pictures, music, or still images, which may be reproduced by electronic entertainment devices and digital cameras, as a replacement of a hard disk in a computer, and an element of a portable information storage medium.

A memory card may include a small-sized card, a compact flash card, a smartmedia card, a secure digital (SD) card, or other type of memory cards. A smartmedia card which may be used to store digital signals and IC cards such as a solid state floppy disc card (SSFDC) may include a COB structure having built-in flash memory chips. However, small-sized cards and compact flash cards have drawbacks because of high non-operation expenses and large volume for a built-in controller.

FIG. 1 illustrates a conventional IC card 10. The IC card 10 may include a COB substrate 12, a flash memory chip 14, and/or a controller chip 16. Bonding patterns 18a and 18b may be formed on the COB substrate 12. The bonding patterns 18a may be electrically connected with bonding pads 16a of the controller chip 16. The bonding patterns 18b may be electrically connected with bonding pads 14a of the flash memory chip 14 and bonding pads 16b of the controller chip 16. Although not illustrated in FIG. 1, the bonding patterns 18a may be electrically connected with pins to interface with an external device.

As illustrated in FIG. 1, the flash memory chip 14 and the controller chip 16 may be arranged on the same planar surface of the COB substrate 12. However, due to decreasing size of an IC card, it may become more difficult to place both the flash memory chip 14 and the controller chip 16 on the same planar surface of the COB substrate 12. In order to overcome this limitation, a stack structure has been proposed.

FIG. 2 illustrates an IC card having a stack structure. A flash memory chip 24 may be placed on a COB substrate 22, and a controller chip 26 may be placed thereon. With this stack structure, bonding pads 26a of the controller chip 26 may be arranged along an edge of the controller chip 26 for electric connection with corresponding bonding patterns 22a. However, the stack structure may require the controller chip 26 to have a rectangle shape rather than a square shape. When a controller chip has a rectangle shape rather than a square shape, problems such chip design, routing inefficiency, increase in chip size, signal delay of internal logic, and the like may occur.

### SUMMARY OF THE INVENTION

Example embodiments according to the invention may provide a semiconductor integrated circuit card having a more efficient COB bonding structure.

In an example embodiment of the present invention, a semiconductor device may include a chip-on-board (COB) substrate having bonding patterns, and a semiconductor chip having a square shape may be disposed on the COB substrate, wherein bonding pads may be arranged along at least two adjacent sides of the semiconductor chip, and a side of the semiconductor chip may be at a desired angle with respect to the bonding patterns.

In another example embodiment of the present invention, a semiconductor integrated circuit (IC) card may include a chip-on-board (COB) board substrate having bonding patterns, external connection pins may be disposed along a peripheral edge of a side on the COB substrate, a first semiconductor chip may be disposed on the COB substrate, and a second semiconductor chip may be arranged on the first semiconductor chip and having bonding pads electrically connected to the bonding patterns, wherein in the second semiconductor chip may have a square shape and the bonding pads of the second semiconductor chip may be arranged along at least two adjacent sides of the second semiconductor chip at a desired angle with respect to the external connection pins.

In yet another example embodiment of the present invention, a semiconductor device may include a chip-on-board (COB) substrate having bonding patterns, and a semiconductor chip may have a square shape disposed on the COB substrate, wherein the semiconductor chip may be arranged to have one of its edge at no more than 90 degrees with respect to the bonding patterns.

### BRIEF DESCRIPTION OF THE DRAWINGS

A better appreciation of example embodiments of the present invention, and aspects thereof, will become readily apparent as the same becomes better understood by reference to the following detailed description when considered in conjuction with the accompanying drawings in which like reference symbols indicate the same or similar components, wherein:

FIGS. 1 and 2 illustrate semiconductor devices with a chip-on-board substrate according to the conventional art; and

FIGS. 3A to 3D illustrate semiconductor integrated circuit cards with a chip-on-board substrate according to example embodiments of the present invention.

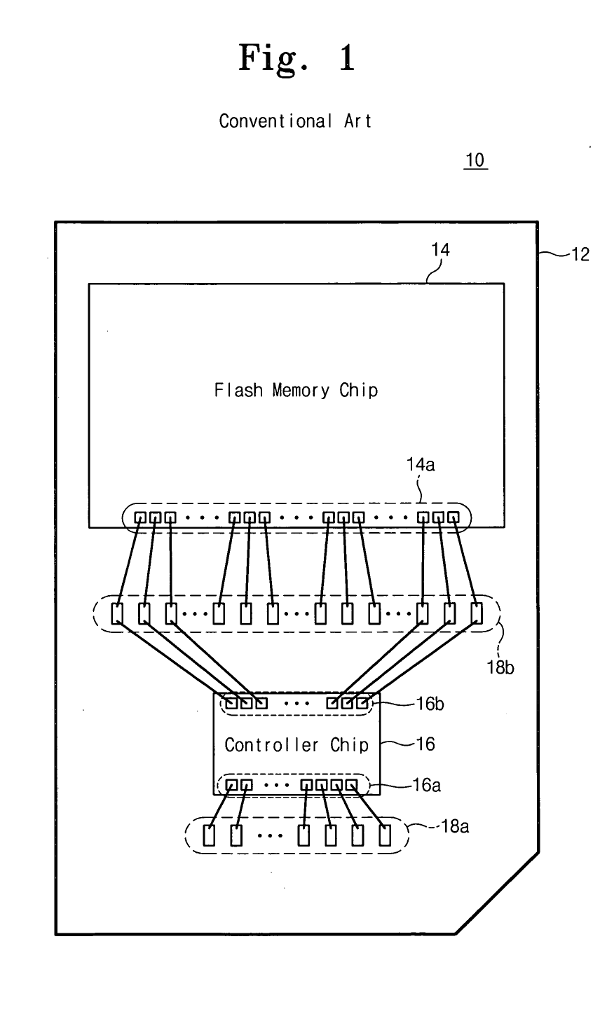

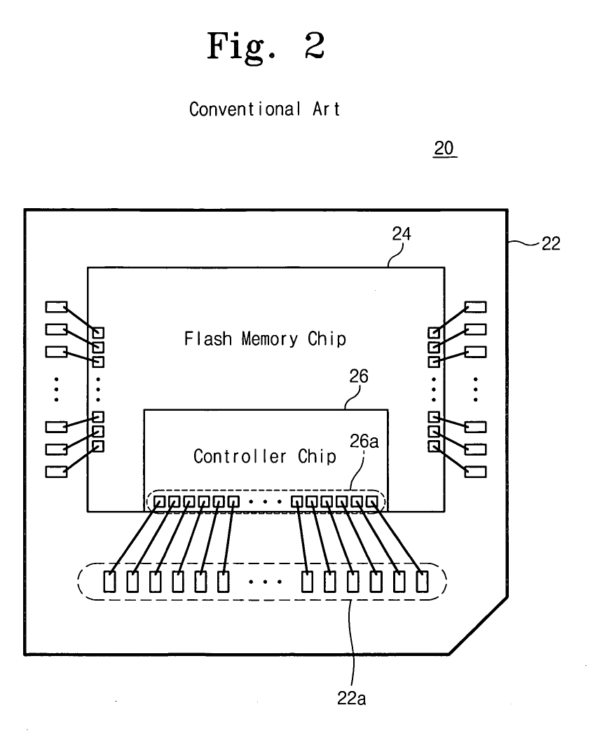

### DESCRIPTION OF EXAMPLE EMBODIMENTS

Example embodiments of the present invention will be more fully described with reference to the attached drawings.

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there may be no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that may be schematic illustrations of idealized embodiments (and intermediate structures) of the present invention. As such, variations from the shapes of the illustrations as a result, for example, of manufacturing techniques and/or tolerances, are to be expected. Thus, the example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

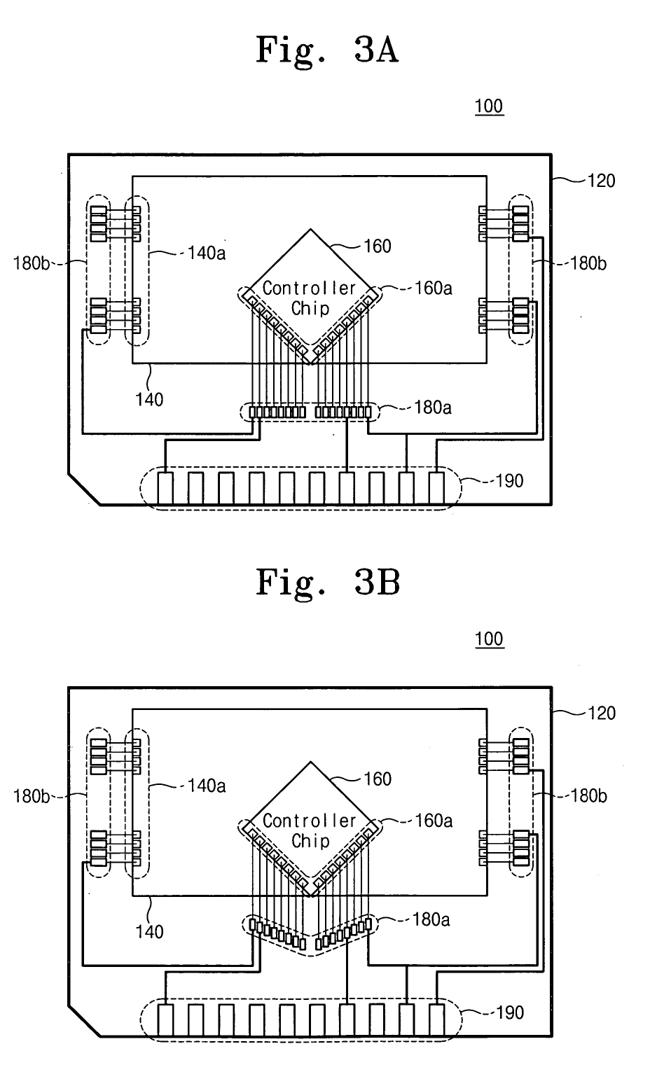

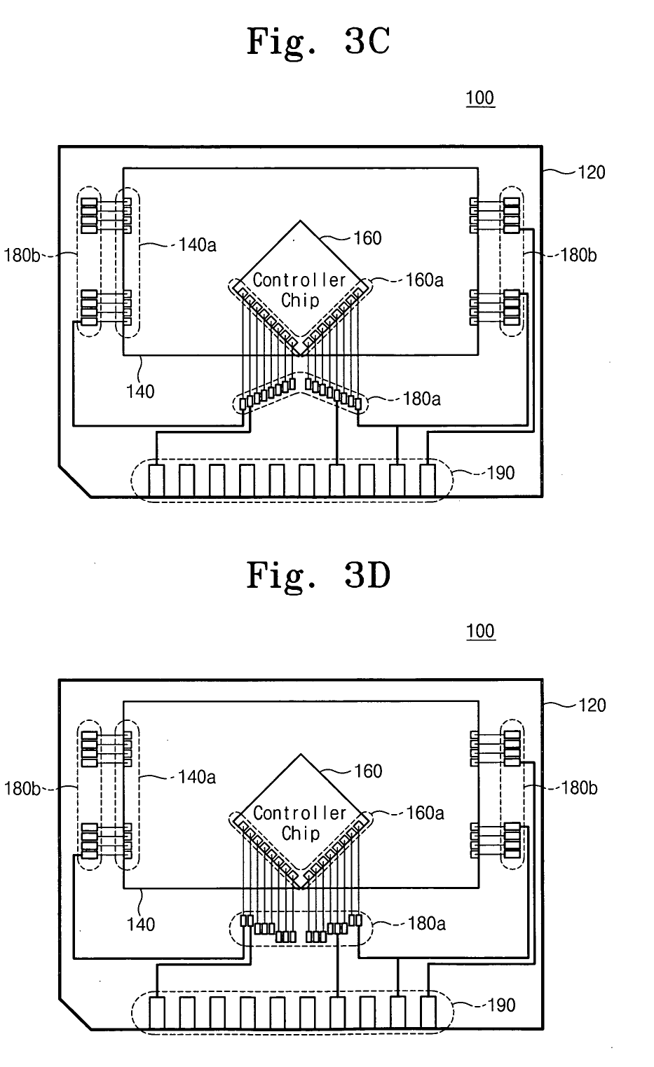

FIGS. 3A to 3D illustrate integrated circuit (IC) cards with a chip-on-board substrate according to example embodiments of the present invention. The IC card may be a portable storage unit and may include a mini SD card, RS-MMC (Reduced Size MMC) card, T-Flash (Trans Flash) card, S-CARD, or other type of memory cards.

Referring to FIG. 3A, an IC card 100 may include a chip-on-board (COB) substrate 120, a flash memory chip 140, and a controller chip 160. First and second bonding patterns 180a and 180b may be formed on the COB substrate 120. The first bonding patterns 180a are electrically connected to corresponding bonding pads 160a of the controller chip 160, and the second bonding patterns 180b may be electrically connected to corresponding bonding pads 140a of the flash memory chip 140. A portion of the first bonding patterns 180a may be electrically connected to pins 190 to interface with an external device, and the remaining first bonding patterns 180a not connected to the bonding pads 160a and the pins 190 may be connected to the second bonding patterns 180b through circuit patterns of the COB substrate 120. The circuit patterns may be also known as “COB wirings.” The first bonding patterns 180a may be arranged in parallel with the pins 190.

As illustrated in FIG. 3A, the controller chip 160 may be arranged on the flash memory chip 140. A side of the controller chip 160 may be disposed at about 45 degree with respect to a side (the side near pins 190) of the COB substrate 120 or the first bonding patterns 180a. In other words, a side of the controller chip 160 may be oriented to an angle of about 45 degree with respect to the first bonding patterns 180a. In accordance with the above-described arrangement of the controller chip 160, the bonding pads 160a may be arranged along two peripheral sides (closest to the first bonding pads 180a) of the controller chip 160. The arrangement of the bonding pads 160a along the two peripheral sides of the controller chip 160 may not be limited to this arrangement, and other arrangements may be used. However, this arrangement may enable the controller chip 160 to be formed in a square shape rather than a rectangle shape. Drawbacks such as difficulty in chip design, low routing efficiency, increase chip size, signal delay of internal logic, and/or other problems due to a rectangle shape controller chip 160 may be solved.

An arrangement of bonding patterns/first bonding patterns 180a according to the example embodiments of the present invention may be varied. For example, as illustrated in FIG. 3A, the bonding patterns 180a may be arranged in a linear pattern; the first bonding patterns 180a may be formed to have a concave arrangement, for example, V-shaped concave arrangement (FIG. 3B); the bonding patterns 180a may be formed to have a convex arrangement, for example, V-shaped convex arrangement (FIG. 3D); the bonding patterns 180a may be formed to have a stepped arrangement, for example, a segmented stepped arrangement (FIG. 3D); and the bonding patterns 180a may be formed to have a mirror arrangement (FIGS. 3A-3D).

As set forth above, COB bonding of a controller chip may be carried out with the controller chip being oriented to a desired angle with respect to a side of a COB substrate. Thus, it may be possible to solve problems of the conventional art.

The present invention has been described using example embodiments. However, it is to be understood that the scope of the present invention may not be limited to the disclosed example embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor device, comprising:
a chip-on-board (COB) substrate having bonding patterns; and
a semiconductor chip having a square shape disposed on the COB substrate, wherein
bonding pads are arranged along at least two adjacent sides of the semiconductor chip, and a side of the semiconductor chip is at a desired angle with respect to the bonding patterns.

2. The semiconductor device of claim 1, wherein the semiconductor chip is a controller chip.

3. The semiconductor device of claim 1, wherein the desired angle is about 45 degrees.

4. The semiconductor device of claim 1, wherein the bonding patterns are arranged in parallel respect to a side of the COB substrate.

5. The semiconductor device of claim 1, wherein the bonding patterns are arranged to have either one of a concave arrangement or a convex arrangement.

6. The semiconductor device of claim 1, wherein the bonding patterns are arranged to have a stepped arrangement.

7. The semiconductor device of claim 1, wherein the two adjacent sides having the bonding pads are nearer to the bonding patterns than the two adjacent sides not having the bonding pads.

8. The semiconductor device of claim 1, wherein the two adjacent sides having the bonding pads are farther from the bonding patterns than the two adjacent sides not having the bonding pads.

9. A semiconductor integrated circuit (IC) card, comprising:
a chip-on-board (COB) board substrate having bonding patterns;
external connection pins disposed along a peripheral edge of a side on the COB substrate;
a first semiconductor chip disposed on the COB substrate; and
a second semiconductor chip arranged on the first semiconductor chip and having bonding pads electrically connected to the bonding patterns,
wherein the second semiconductor chip has a square shape and the bonding pads of the second semiconductor chip are arranged along at least two adjacent sides of the second semiconductor chip at a desired angle with respect to the external connection pins.

10. The semiconductor IC card of claim 9, wherein the first semiconductor chip is a flash memory chip and the second semiconductor chip is a controller chip.

11. The semiconductor IC card of claim 9, wherein the desired angle is about 45 degrees.

12. The semiconductor IC card of claim 9, wherein the bonding patterns are arranged in parallel with respect to the external connection pins.

13. The semiconductor IC card of claim 9, wherein the bonding patterns are arranged to have either one of a concave arrangement and a convex arrangement.

14. The semiconductor IC card of claim 9, wherein the bonding patterns are arranged to have a stepped arrangement.

15. The semiconductor IC card of claim 9, wherein the two adjacent sides having the bonding pads are nearer to the bonding patterns than the two adjacent sides not having the bonding pads.

16. The semiconductor IC card of claim 9, wherein the two adjacent sides having the bonding pads are farther to the bonding patterns than the two adjacent sides not having the bonding pads.

17. The semiconductor IC card of claim 9, wherein the bonding patterns include and first bonding patterns and second bonding patterns.

18. The semiconductor IC card of claim 17, wherein the first bonding patterns are electrically connected to the bonding pads of the second semiconductor chip, and the second bonding patterns are electrically connected to bonding pads of first semiconductor chip.

19. The semiconductor IC card of claim 17, wherein the first and second bonding patterns are electrically connected to the external connection pins.

20. A semiconductor device, comprising:
a chip-on-board (COB) substrate having bonding patterns; and
a semiconductor chip having a square shape disposed on the COB substrate, wherein the semiconductor chip is arranged to have at least one of its edges at no more than 90 degrees with respect to the bonding patterns.
